(19) United States
(12) Patent Application Publication
(10) Pub. No.: US 2003/0103583 A1
(43) Pub. Date: Jun. 5, 2003

(54) Method and apparatus for multi-level phase shift keying communications

(75) Inventors: Kay Soon Low, Singapore (SG); Kin Mun Lye, Singapore (SG); Paul Kar Ming Ho, Singapore (SG)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: NATIONAL UNIVERSITY OF SINGAPORE, SINGAPORE (SG)

(21) Appl. No.: 10/096,150

(22) Filed: Mar. 11, 2002

Related U.S. Application Data
(60) Provisional application No. 60/337,198, filed on Dec. 4, 2001.

(51) Int. Cl. H03D 3/22; H04L 27/22

(52) U.S. Cl. 375/329

(57) ABSTRACT

Methods and apparatus for detecting multiple-level phase shift keying (MPSK) signals based on detectors that have nonlinear dynamics transfer characteristics are disclosed. The receiver circuit can be implemented easily using devices such as the op-amps to provide the required dynamic characteristics. The performance is enhanced by transmitting multiple cycles of the PSK signals and gating of the received waveforms.

### CROSS-REFERENCES TO RELATED APPLICATIONS

This application claims the benefit of U.S. Provisional Application No. 60/336,198, filed Dec. 4, 2001, entitled “METHOD AND APPARATUS FOR MULTI-LEVEL PHASE SHIFT KEYING COMMUNICATIONS.”

### STATEMENT AS TO RIGHTS TO INVENTIONS MADE UNDER FEDERALLY SPONSORED RESEARCH AND DEVELOPMENT

NOT APPLICABLE

### REFERENCE TO A “SEQUENCE LISTING,” A TABLE, OR A COMPUTER PROGRAM LISTING APPENDIX SUBMITTED ON A COMPACT DISK

NOT APPLICABLE

### BACKGROUND OF THE INVENTION

This invention relates generally to techniques for generating pulses and more specifically to techniques for converting arbitrary analog waveforms to produce sequences of pulses.

Phase Shift Keying (PSK) is a well-known modulation scheme and is used in much communication equipment. It has the best performance in an additive white Gaussian noise (AWGN) channel as compared to other modulation techniques, such as Frequency Shift Keying (FSK) and On Off Keying (OOK). For typical communication equipment that uses the PSK scheme, a coherent detector is used to recover the encoded digital information from a PSK modulated carrier. As many carrier cycles are required to recover the encoded symbol, the carrier frequency is usually very high as compared to the modulating signal.

In commonly owned, co-pending U.S. Patent Application No. 09/850,713, filed May 7, 2001, entitled “Method & Apparatus for Generating Pulses from Phase Shift Keying Analog Waveforms,” it discloses a receiver that is developed based on nonlinear circuits (commonly owned U.S. Pat. No. 6,259,390, incorporated herein for all purposes) that generate pulses from analog waveforms. The receiver configuration is capable of decoding one cycle of analog waveform to produce a group of pulses. Though the receiver system is efficient, further enhancement in performance is needed in the pulse processing subsystem.

### BRIEF SUMMARY OF THE INVENTION

A method and apparatus for detecting a received PSK modulated signal is disclosed. In one embodiment of the invention, the transmitted signal is an information waveform representative of one or more symbols to be communicated. The received signal is processed to produce a pulse waveform comprising groups of pulses. A detection waveform is used to mask out extraneous pulses that do not correspond to the information waveform. The remaining groups of pulses are then decoded by a pulse processing system to reproduce the original symbols.

### BRIEF DESCRIPTION OF THE DRAWINGS

The teaching of the present invention can be readily understood by considering the following detailed description in conjunction with the accompanying drawings:

FIG. 1 shows a simplified block diagram of the transmitter in an illustrative embodiment of the present invention;

FIG. 2 shows a simplified block diagram of the receiver in an illustrative embodiment of the present invention;

FIG. 3 illustrates a typical transfer curve which characterizes the circuitry of the present invention;

FIG. 4 shows the ideal received waveform and the gating signals for the BPSK modulation scheme;

FIG. 5 illustrates a receiver circuit having two detectors for the communication system, according to an embodiment of the present invention;

FIG. 6 shows the waveforms of the transmission and detection process based on BPSK modulation scheme;

FIG. 7 shows the waveforms of the transmission and detection process based on QPSK modulation scheme; and

FIG. 8 shows the waveforms of the transmission and detection process based on multiple cycle per symbol transmission.

### DETAILED DESCRIPTION OF THE INVENTION

FIG. 1 shows a block diagram of the transmitter, according to an embodiment of the present invention.

The digital information source is shown as the block 10. The MPSK modulator 11 modulates the digital source waveform to the desired MPSK signals (e.g., BPSK, QPSK, 8PSK, 16PSK etc) for transmission. To improve the BER performance, we can also use multiple cycles per symbol (e.g., 4 cycles per symbol etc) to encode each symbol. The modulated signal 12 is then amplified and/or wave shaped or up-converted to suitable wave 14 before being sent to the communication channel. The channel can be wire-line or wireless. In FIG. 1, an antenna 15 is shown for the case of a wireless channel.

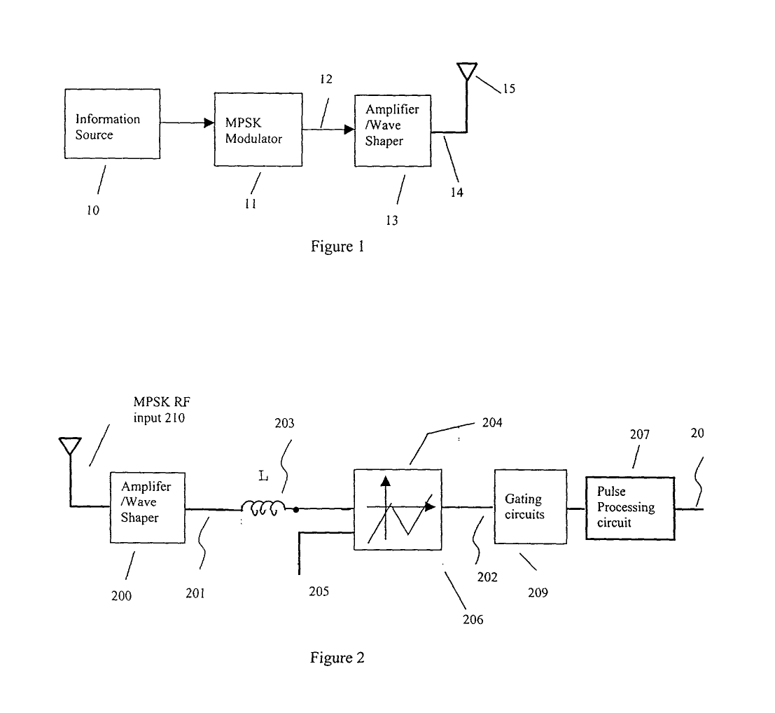

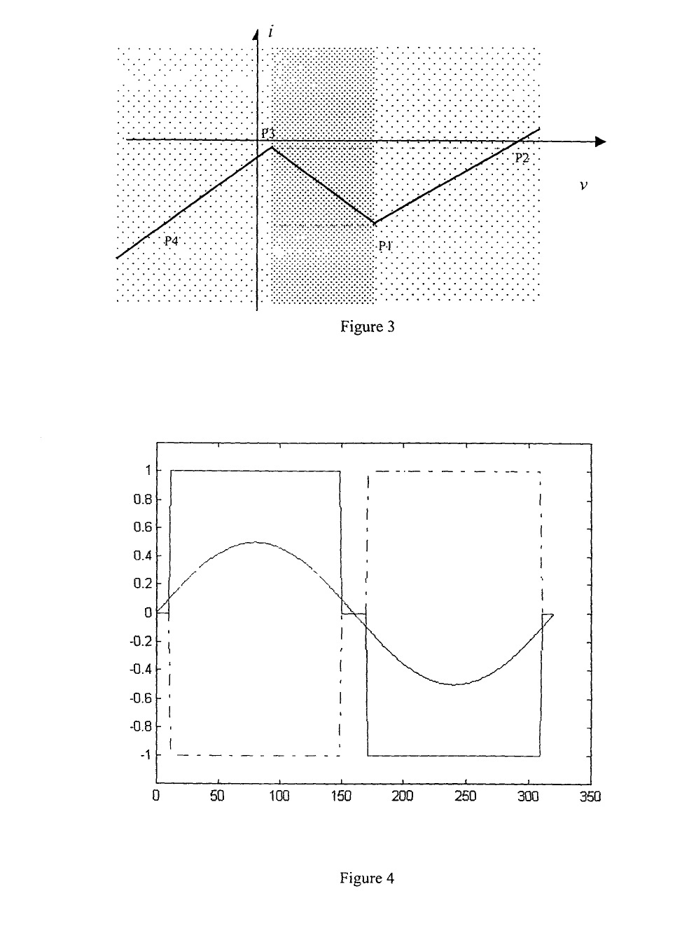

FIG. 2 shows the receiver system of the invention. For the case of a wireless channel, the system comprises an antenna 210 which receives the MPSK modulated transmitted signal. The received signals may pass through an optional amplifier and/or wave shaper circuit, or down-converter 200 to condition the incoming signal to make it suitable for optimum detection by the subsequent circuit. The conditioned signal 201 from the circuit 200 is then fed to a nonlinear circuit combination 206, comprising an inductor 203 connected in series to a circuit 204. The circuit 204 has an N-shaped I-V characteristic as shown in FIG. 3 with the impasse points positioned as shown. The lower impasse point is located at a small positive voltage.

The output 202 from the circuit 204 comprises groups of pulses or periods of silence depending on the received signals. A gating circuit 209 and a pulse processing circuit 207 then determine the appropriate decoded digital signal 208 based on the received groups of pulses. The gating circuit sets suitable timing windows which are temporally aligned with the information waveform at the transmitting end of a communication system.

The gating function serves to mask out those pulses which do not correspond to the pulses in the original information waveform, while leaving the remaining groups of pulses which correspond to the information waveform intact. By detecting the number of pulses in each group, we can reproduce the symbols represented by the information waveform. This approach improves the receiver BER performance substantially. In the case of BPSK signals, two gating circuits are used, each with a different gating window as shown in FIG. 4.

The characteristic curve of the circuit 204 is shown in FIG. 3. The transfer curve has two impasse points P1=(V_{v,} iᵥ) and P3=(V_{p,} iₚ). Here, iᵥ and iₚ represent the valley and the peak current of the N curve. In general, we do not require that the curves be piecewise linear. The only requirement is that the characteristic curve consists of three distinct regions such that the middle region is having negative impedance slope, while the two external regions are having positive impedance slopes. Under the condition that the input signal is operating at the line segment P1-P3 of the characteristic curve, pulses will be generated which traveled along the state trajectory P4 P3 P2 P1 P4. The number of pulses being generated depends on the available time (i.e., the duration that the input signal is operating on the line segment P1-P3) and the speed of the trajectory.

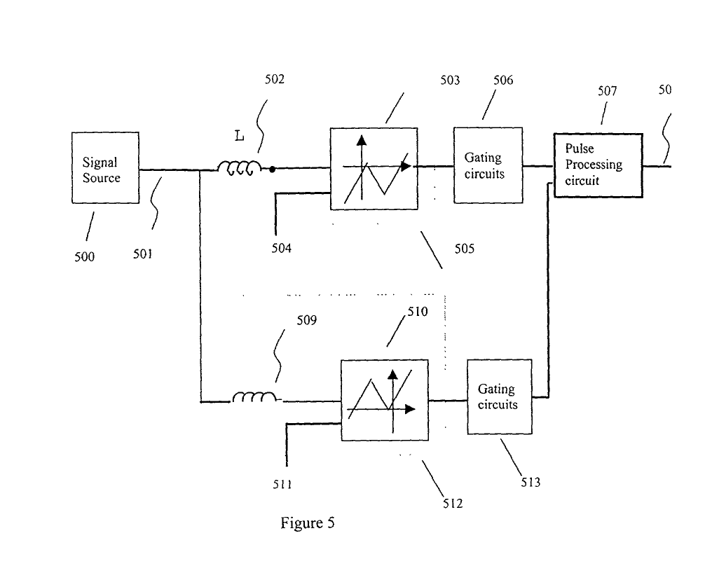

Referring now to FIG. 5, we show another receiver configuration that is used in the form of dual detector mode.

In this illustrative embodiment of the invention, a duo detector configuration is shown and it can also be extended to multiple detector configurations. The I-V characteristics of each N-type circuit may be constructed to have different set of impasse points, so that it responds to the input signals differently than another of the N-type circuits, which is characterized by its own set of impasse points.

Similar to the single detector system, the second detector circuit 512 also consists of an inductor 509 and another nonlinear circuit 510 connected in series. The nonlinear circuit 5 10 also has an N-type I-V transfer characteristics. However, the transfer curve is positioned at different location by applying suitable voltage at the input 511, and biasing etc. The input 504 and 511 can also be used to dynamically manipulate the transfer curves. The output from the circuit 512 also consists of a series of pulses or silences depending on the received signals. As the transfer curves of the circuits 505 and 512 are different, they responded to the same input signal 501 differently.

The pulse processing circuit counts the number of pulses that occur in each gating circuit outputs and form a metric. Based on the values of the metric, it determines which is the most likely symbol being transmitted.

Next, we describe the response of the system in FIG. 5. In the following, we first explain using M=2-ary BPSK modulation scheme.

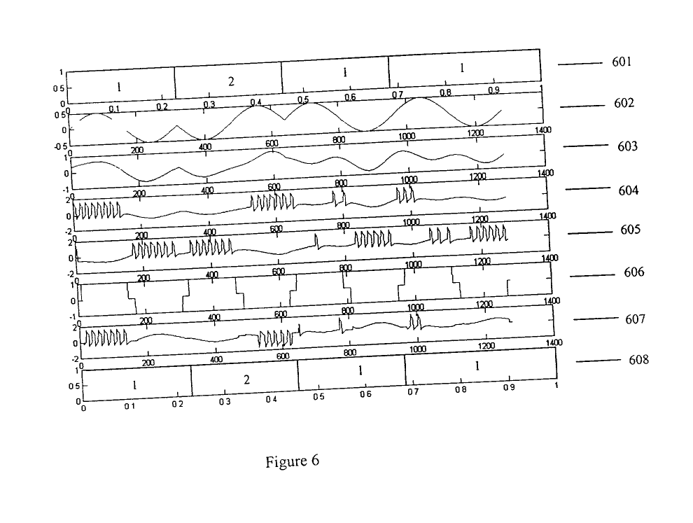

FIG. 6 illustrates a typical response of the receiver shown in FIG. 4 based on numerical simulation. The waveform 601 is the symbol to be transmitted. In this illustrative example, the signal that is being transmitted is the symbol {1 2 1 1 }. The BPSK signal is shown as the waveform 602. Due to the additive white Gaussian noise presence in the channel, the received signal is corrupted and is shown as the waveform 603. The outputs from the two nonlinear circuits 505 and 512 comprise a series of pulses depending on the location of the signals as well as the level of the noises. This is shown as the waveform 604 and 605 for the positive and negative detectors in FIG. 5 respectively. Depending on the tuning of the nonlinear circuit, the presence of the digital signal can be set to generate a specified number of pulses. In this illustrative example, seven pulses are generated if a low noise signal is received. The waveform 606 shows the gating waveform for the symbol 1. The gating waveform has two weighting values of ±1. The waveform 607 shows the signals after the gating function. Upon receiving these pulses, the pulse processing system determines the decoded digital signals. Essentially, the pulse processing system performs the following tasks: 1. For each half cycle, calculate the metric of each symbol δᵢ, 0≦i≦M−1, by summing the number of positive and negative pulses. 2. Compare the metrics of each symbol and decides that xₘ(t) is the most likely transmitted symbol if δₘ is the largest amongst all the δᵢ. In this illustrative example shown in FIG. 6, the decoded symbol is shown as 608 which is the same as the symbol sent.

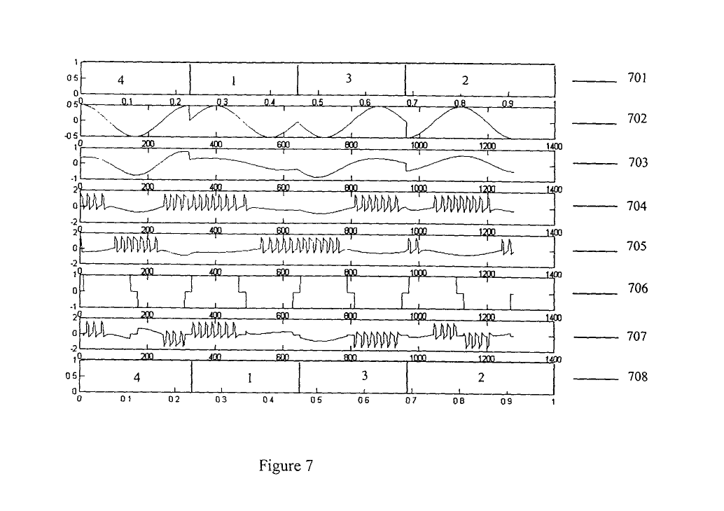

FIG. 7 illustrates another example for the case of QPSK modulation scheme. In this case, the symbol that is being sent is {4 1 3 2} which is shown as 701. The transmitted signal is shown as waveform 702. The received waveform is shown as 703. The pulses that are generated from the two N-type circuits are shown as 704 and 705. The gating signals for the symbol 1 is shown as 706. The resultant signals after the gating function is illustrated as 707 and the recovered symbols are shown as 708.

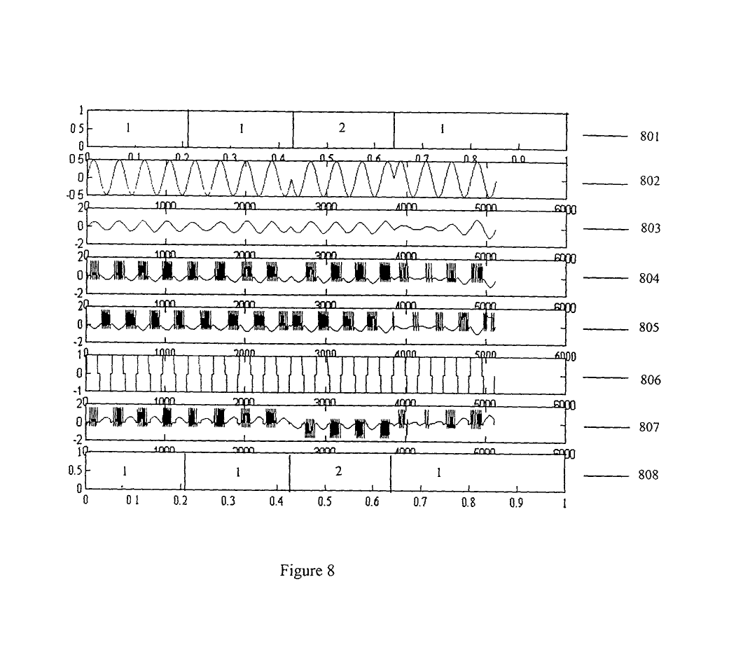

The bit error rate performance of the receiver can be improved by employing multiple cycle per symbol for the transmission. FIG. 8 illustrates the response with four cycles per symbol based on the BPSK scheme. In the figure, the symbol that is being transmitted is the symbol set {1 1 2 1 } shown as 801. The BPSK signal is shown as 802 and the noisy received signal is 803. Pulses are generated at the output of the nonlinear circuits and are shown as 804 and 805. These pulses are passed through gating circuits and the waveform 806 shows a gating signal for the symbol 1. The resultant signal is shown as 807 and recovered symbols are shown as 808.

What is claimed is:

1. A method for detection of a phase shift keying (PSK) signal comprising:
for each cycle of said PSK signal (i) producing a first group of at least one pulse based on a positive portion of said cycle and (ii) producing a second group of at least one pulse based on a negative portion of said cycle;
applying at least one gating window to said first and second groups to retain at least one pulse within said at least one gating window and disregard at least one pulse outside of said at least one gating window; and
producing an information symbol on the basis of at least one pulse retained by said at least one gating window.

2. The method of claim 1 wherein said at least one gating window comprises a portion of a gating window waveform that is time-aligned to said PSK signal.

3. The method of claim 1 wherein said at least one gating window has a zero value near the beginning and near the end of said at least one gating window and wherein said at least one gating window is non-zero elsewhere.

4. The method of claim 1 further including providing a first circuit configured to produce said first group in response to detecting said positive portion of said cycle and providing a second circuit configured to produce said second group in response to detecting said negative portion of said cycle.

5. The method of claim 4 wherein said first and second circuits each has a transfer function characterized by an unstable region bounded by stable regions.

6. The method of claim 1 wherein said information symbol producing step includes counting pulses retained by said at least one gating window from said first and second groups to respectively produce first and second pulse counts, said information symbol being produced based on said pulse counts.

7. The method of claim 6 wherein said counting includes weighting the contribution of said pulses to a pulse count depending on which portion of said PSK signal said pulses were produced.

8. The method of claim 6 wherein for said first group, some of said pulses contribute more than one count to said first pulse count.

9. The method of claim 1 wherein said first group producing step includes limiting a maximum positive amplitude of said positive portion of said cycle to a first value.

10. The method of claim 9 wherein said limiting is a step of clamping said PSK signal.

11. The method of claim 1 wherein said first group of has positive-going pulses and said second group has negative-going pulses.

12. The method of claim 1 further including combining said first and second groups prior to said producing an information symbol.

13. The method of claim 1 further including producing a synchronization signal from said PSK signal, said step of producing an information signal including detecting said first group and said second group based on said synchronization signal.

14. The method of claim 13 wherein said synchronization signal is a sinusoidal signal having a frequency substantially equal to the frequency of a sinusoidal waveform used to represent a PSK symbol.

15. The method of claim 1 wherein said PSK signal is a binary phase shift keying (BPSK) signal.

16. The method of claim 1 wherein said PSK signal is a quaternary phase shift keying (QPSK) signal.

17. The method of claim 1 further including receiving a transmitted signal and producing said PSK signal from said transmitted signal.

18. The method of claim 1 wherein said information symbol is produced from multiple cycles of said PSK signal, on the basis of at least one pulse retained by said at least one gating window from said first and second groups corresponding to said multiple cycles of said PSK signal.

19. A circuit system for detecting a phase shift keying (PSK) signal comprising:
a first circuit configured to produce a plurality of groups of at least one positive pulse in response to detecting first portions of said PSK signal;
a second circuit configured to produce a plurality of groups of at least one negative pulse in response to detecting second portions of said PSK signal;
a windowing circuit configured to receive said plurality of groups of at least one positive pulse and said plurality of groups of at least one negative pulse, said windowing circuit also configured to retain at least one pulse within at least one gating window and disregard at least one pulse outside of said at least one gating window; and
a decoder configured to produce a plurality of information symbols based said at least one pulse retained by said at least one gating window.

20. A phase shift keying (PSK) detection system comprising:
means for receiving a transmitted PSK signal;
first means for producing a plurality of positive pulses from said received signal;
second means for producing a plurality of negative pulses from said received signal;
windowing means for applying at least one gating window to said plurality of positive pulses and said plurality of negative pulses to retain at least one pulse within said at least one gating window and disregard at least one pulse outside of said at least one gating window; and
symbol means for producing information symbols from said at least one pulse retained by said at least one gating window.
